(19) United States
(12) Patent Application Publication
(10) Pub. No.: US 2012/0184066 A1
(43) Pub. Date: Jul. 19, 2012

(54) SINTERED In-Ga-Zn-O-TYPE OXIDE

(75) Inventors: Koki Yano, Sodegaura-shi (JP); Hirokazu Kawashima, Sodegaura-shi (JP); Masayuki Itose, Sodegaura-shi (JP); Kauzyoshi Inoue, Sodegaura-shi (JP)

(73) Assignee: IDEMITSU KOSAN CO., LTD., Tokyo (JP)

(21) Appl. No.: 13/261,239

(22) PCT Filed: Sep. 30, 2010
(86) PCT No.: PCT/JP2010/005885

§ 371 Date: Mar. 28, 2012

(30) Foreign Application Priority Data
Sep. 30, 2009 (JP) 2009-226447

(51) Int. Cl. H01L 21/20; C23C 14/08; C04B 35/64; C23C 14/34

(52) U.S. Cl. 438/104; 204/298.13; 264/681; 257/E21.09

(57) ABSTRACT

An oxide sintered body including In (indium element), Ga (gallium element) and Zn (zinc element), having a total content of In, Ga and Zn relative to total elements except for an oxygen element of 95 at % or more, and including a compound having a bixbyite structure represented by In₂O₃ and a compound having a spinel structure represented by ZnGa₂O₄.

### TECHNICAL FIELD

The invention relates to an oxide sintered body. In particular, the invention relates to an oxide sintered body suited for the formation of an amorphous oxide film by sputtering.

### BACKGROUND ART

A field effect transistor such as a thin film transistor (TFT) is widely used as a unit electronic device of a semiconductor memory integrated circuit, a high-frequency signal amplification device and a liquid crystal driving device. A field effect transistor is an electronic device which is most widely put into practice currently. Of these, with a significant development of a display in recent years, in various displays such as a liquid crystal display (LCD), an electroluminescence display (EL) and a field emission display (FED), a TFT is frequently used as a switching device for driving a display by applying a driving voltage to a display device.

As the material for the semiconductor layer (channel layer) which is the main component of the field effect transistor, a silicon semiconductor compound is most widely used. In general, in a high-frequency signal amplification device, an integrated circuit device or the like which require a high-speed operation, silicon mono-crystals are used. On the other hand, for a device for liquid crystal driving or the like, due to the need of an increase in size, an amorphous silicon semiconductor (amorphous silicon) has been used.

An amorphous silicon thin film can be formed at a relatively low temperature. However, since the switching speed thereof is low as compared with a crystalline thin film, when used as a switching device for driving a display, it may not follow the display of a high-speed moving image. Specifically, in the case of a liquid crystal TV of which the resolution is VGA, amorphous silicon having a mobility of 0.5 to 1 cm²/Vs can be used. However, if the resolution is SXGA, UXGA, GXGA or higher, a mobility of 2 cm²/Vs or more is required. In addition, a further high degree of mobility is required if the driving frequency is increased in order to enhance the image quality.

On the other hand, although a crystalline silicon-based thin film has a high degree of mobility, it has a problem that a large amount of energy and a large number of steps are required for the production and that an increase in area is difficult. For example, when crystallizing a silicon-based thin film, laser annealing which requires a high temperature of 800° C. or higher or expensive equipment is required. Further, as for a crystalline silicon-based thin film, since the device configuration of a TFT is normally restricted to a top-gate structure, a decrease in cost such as reduction in number of mask is difficult.

In order to solve the problem, a thin film transistor using an amorphous oxide semiconductor film formed of indium oxide, zinc oxide and gallium oxide has been studied. In general, formation of an amorphous oxide semiconductor thin film is conducted by sputtering using a target (sputtering target) formed of an oxide sintered body.

For example, a target formed of a compound showing a homologous crystal structure represented by the general formula In₂Ga₂ZnO_{7-d}InGaZnO₄ is published (Patent Documents 1, 2 and 3). However, in this target, it is required to conduct sintering in an oxidation atmosphere in order to increase the sintering density (relative density). In this case, in order to decrease the resistance of a target, a reduction treatment is required to be conducted at a high temperature after sintering. Further, if a target is used for a long period of time, there were problems that the properties or the film-forming speed of the resulting film vary greatly, abnormal discharge due to abnormal growth of InGaZnO₄ or In₂Ga₂ZnO₇ occurs, and particles are generated frequently during the film formation or the like.

Further, studies were made mainly on the case in which the atomic ratio of In, Ga and Zn is almost equivalent, and specific studies on a composition in which the amount of Zn is small and the amount of Ga is large (for example, atomic ratio: In:Ga:Zn=40:40:20; specifically a composition in which Zn is less than 30 at % and Ga is 35 at % or more) are not sufficient (Patent Document Nos. 2, 3 and 4).

As mentioned above, studies on a target which is used for forming an oxide semiconductor film by sputtering are not sufficient.

On the other hand, Non-Patent Document 1 discloses studies on the relationship of each phase of In₂Ga₂ZnO₇ and ZnGa₂O₄ and ZnO using a sintered body comprising indium oxide, zinc oxide and gallium oxide synthesized by a reaction in a platinum tube. However, no studies were made on the method or properties of an oxide sintered body or the crystal type or target properties suited for a sputtering target for the formation of an oxide semiconductor.

As for an oxide formed of a compound having a bixbyite structure represented by In₂O₃ and a compound having a spinel structure represented by ZnGa₂O₄, it has been known that there are two cases; i.e. an oxide obtained by heating for a long period of time (12 days) powder of (InGaO₃)₂ZnO (Non-Patent Document 1) and an oxide obtained in the form of powder by decomposition of InGaZnO₄ when being subjected to a heat treatment in a reduction atmosphere (Non-Patent Document 2). However, the physical properties or a method for preparing as an oxide sintered body has not been studied.

An oxide in which In₂O₃ is doped in ZnGa₂O₄ has been studied as a fluorescent substance. However, this oxide has a small amount of the compound having a bixbyite structure represented by In₂O₃, and hence, has a high resistance. Therefore, this oxide was not studied as an oxide sintered body or a sputtering target (Non-Patent Document 3).

### RELATED ART DOCUMENTS

### Patent Documents

Patent Document 1: JP-A-08-245220
Patent Document 2: JP-A-2007-73312
Patent Document 3: WO2009/084537
Patent Document 4: WO2008/072486

### Non-Patent Documents

Non-Patent Document 1: N. Kimizuka et al., Journal of Solid State Chemistry, Volume 116, Issue 1, 1995, Pages 170-178
Non-Patent Document 2: In-KeunJenong et al., Solid State Communications, Volume 108, 11 (1998) 823
Non-Patent Document 3: Su-Hua Yang et al., J. Vac. Sci. Technol., Al19 (5) 2463 (2001)

### SUMMARY OF THE INVENTION

An object of the invention is to obtain an oxide sintered body for forming an oxide semiconductor film having a low resistance, a high relative density, a high transverse rupture strength and high film formation reproducibility.

As mentioned above, a sputtering target formed of a compound having a homologous crystal structure represented by In₂Ga₂ZnO_{7-d} or InGaZnO₄ has problems in production process or film-forming properties. In order to solve these problems, the inventors made intensive studies. As a result, the inventors have found that a sputtering target formed of an oxide sintered body comprising both a bixbyite structure represented by In₂O₃ and a spinel structure represented by ZnGa₂O₄ does not require a reduction treatment at a high temperature which is conducted to lower the resistance and is excellent in film formation stability or reproducibility. The invention has been made based on this finding.

According to the invention, the following oxide sintered body or the like are provided.

1. An oxide sintered body comprising In (indium element), Ga (gallium element) and Zn (zinc element), having a total content of In, Ga and Zn relative to total elements except for an oxygen element of 95 at % or more, and comprising a compound having a bixbyite structure represented by In₂O₃ and a compound having a spinel structure represented by ZnGa₂O₄.
2. The oxide sintered body according to 1, wherein the atomic ratio of Ga relative to the total of In, Ga and Zn satisfies the following formula (1) and the atomic ratio of Zn relative to the total of In, Ga and Zn satisfies the following formula (2):

0.20<Ga/(In+Ga+Zn)<0.49 (1)

0.10<Zn/(In+Ga+Zn)<0.30 (2).

3. The oxide sintered body according to 1 or 2, wherein one of the compound having a bixbyite structure represented by In₂O₃ and the compound having a spinel structure represented by ZnGa₂O₄ is the first (primary) component and the other is the second (sub) component.
4. The oxide sintered body according to any of 1 to 3, wherein, in the X-ray diffraction (XRD), the ratio (I(ZnGa₂O₄)/I(In₂O₃)) of the maximum peak intensity (I(In₂O₃)) of the compound having a bixbyite structure represented by In₂O₃ and the maximum peak intensity (I(ZnGa₂O₄)) of the compound having a spinel structure represented by ZnGa₂O₄ is 0.80 or more and 1.25 or less.
5. The sintered body according to any of 1 to 4, which has a relative density of 90% or more, a resistivity measured by the four probe method of 50 mΩcm or less and the number of black spots on the surface is 0.1/cm² or less.
6. The oxide sintered body according to any of 1 to 5, wherein the metal elements contained are substantially In, Ga and Zn.
7. The oxide sintered body according to any of 1 to 5, which further comprises a positive tetravalent element X, wherein the atomic ratio of X relative to the total of In, Ga, Zn and X satisfies the following formula (3):

0.0001<X/(In+Ga+Zn+X)<0.05 (3).

8. The oxide sintered body according to 7, wherein X is at least one selected from the group consisting of Sn, Ge, Zr, Hf, Ti, Si, Mo and W.
9. The oxide sintered body according to 7 or 8 wherein the metal element contained is substantially In, Ga, Zn and the positive tetravalent element X.
10. A sputtering target comprising the oxide sintered body according to any of 1 to 9.
11. A method for producing the oxide sintered body according to any of 1 to 9, which comprises the step of sintering a shaped body formed of a raw material comprising indium oxide powder, gallium oxide powder and zinc oxide powder at 1160 to 1380° C. for 1 to 80 hours.
12. The method for producing the oxide sintered body according to 11, wherein the pressurization with oxygen during the sintering step is conducted at 1 to 3 atmospheric pressures.
13. The method for fabricating a semiconductor device which comprises the step of forming an amorphous oxide film by using the sputtering target according to 10.

According to the invention, an oxide sintered body having a low resistivity, a high relative density and a high transverse rupture strength can be provided.

### BRIEF DESCRIPTION OF THE DRAWINGS

FIG. 1 is a schematic cross-sectional view showing one embodiment of a thin film transistor;

FIG. 2 is an X-ray diffraction chart of a sintered body prepared in Example 1;

FIG. 3 is an X-ray diffraction chart of a sintered body prepared in Example 2;

FIG. 4 is an X-ray diffraction chart of a sintered body prepared in Comparative Example 1;

FIG. 5 is an X-ray diffraction chart of a sintered body prepared in Comparative Example 2; and

FIG. 6 is a photograph showing black spots on the surface of a target prepared in Comparative Example 3.

### MODE FOR CARRYING OUT THE INVENTION

The sintered oxide body of the invention comprises In (indium element), Ga (gallium element) and Zn (zinc element). The total content of In, Ga and Zn relative to the total elements of the oxide sintered body except for an oxygen element is 95 at % or more. If the content is less than 95 at %, the relative density of the oxide sintered body may decrease or the mobility of a thin film transistor may be lowered when it is fabricated. It is preferred that the total content be 99 at % or more.

The atomic ratio of each element contained in the oxide sintered body can be obtained by quantitatively analyzing the elements contained by means of an inductively coupling plasma atomic emission spectroscopy analyzer (ICP-AES).

Specifically, in an analysis using an ICP-AES, when introducing a solution sample into an argon plasma (about 6000 to 8000° C.) after turning it into a fine mist by means of a nebulizer, an element in the sample is excited by absorbing thermal energy, and as a result, orbit electrons are transferred to an orbit with a higher energy level. These level electrons are transferred to an orbit with a lower energy orbit within 10⁻⁷ to 10⁻⁸ seconds. At this time, difference in energy is radiated and emitted as light. Since this light has a wavelength (spectrum line) peculiar to the element, presence of the element can be confirmed by the presence of a spectrum line (qualitative analysis).

In addition, since the magnitude of each spectrum line (emission intensity) is increased in proportion to the number of electrons in the sample, the sample concentration can be obtained by comparing with the standard solution with a known concentration (qualitative analysis).

After specifying the contained element by a qualitative analysis, the contained amount was determined by a qualitative analysis, whereby the atomic ratio of the elements is obtained from the results.

The oxide sintered body of the invention is formed of an oxide sintered body comprising a compound having a bixbyite structure represented by In₂O₃ and a compound having a spinel structure represented by ZnGa₂O₄. As a result, an oxide sintered body having a low resistivity, a high relative density and a high transverse rupture strength can be obtained.

Here, the “bixbyite structure represented by In₂O₃” (a C-type crystal structure of a rare earth oxide) means a cubic crystal system having a space group represented by (Tₕ⁷, Iₐ₃), and is also referred to as a Mn₂O₃(I) type oxide crystal structure. For example, Sc₂O₃, Y₂O₃, TI₂O₃, Pu₂O₃, Am₂O₃, Cm₂O₃, In₂O₃ and ITO (one obtained by doping In₂O₃ with Sn in an amount of about 10 wt % or less) show this crystal structure (see “Technology of Transparent Conductive Film”). The presence of a compound having a bixbyite structure represented by In₂O₃ in the oxide sintered body can be confirmed by the fact that it shows a pattern of the JCPDS card No. 6-0416 in the X-ray diffraction (XRD).

The crystal structure of the bixbyite structure represented by In₂O₃ (stoichiometric ratio: M₂X₃) is a structure in which one of four anions are withdrawn from a fluorite type crystal structure, which is one of the crystal structure of a compound represented by MX₂ (M: cation, X: anion). Specifically, six anions (normally, oxygen in the case of an oxide) are coordinated relative to an cation, and the remaining two anion sites are vacant (the vacant anion sites are also called as the “quasi-ion site” (see “Technology of Transparent Conductive Film”). The crystal structure of the bixbyite structure represented by In₂O₃ in which 6 oxygen atoms (anions) are coordinated relative to a cation has an oxygen octahedron ridge-sharing structure. Due to the presence of the oxygen octahedron ridge-sharing structure, the ns orbit of a p metal as a cation is overlapped one on another to form an electron conductive path. As a result, the effective mass is decreased to show a high electron mobility.

Further, the crystal structure of the bixbyite structure represented by In₂O₃ tends to generate oxygen deficiency easily. Therefore, it is possible to allow oxygen deficiency to be generated in the crystal structure of the bixbyite structure represented by In₂O₃ without conducting a reduction treatment to lower the resistance.

As for the crystal structure of the bixbyite structure represented by In₂O₃, the stoichiometric ratio may be shifted from M₂X₃ as long as it shows the pattern of the JCPDS card No. 6-0416 in the X-ray diffraction. That is, it may be M₂O_{3-d}. It is preferred that the amount of oxygen deficiency d be in the range of 3×10⁻⁵ to 3×10⁻¹. d can be adjusted by sintering conditions, atmosphere at the time of sintering, heating and cooling or the like. Further, it can be adjusted by conducting a reduction treatment or an oxidation treatment after sintering. The amount of oxygen deficiency is a value obtained by deducting the number of oxygen ions contained in one mole of an oxide crystal from the stoichiometric amount of oxygen ions and expressed in terms of mole.

The number of oxygen ions contained in an oxide crystal can be calculated by measuring the amount of carbon dioxide generated by heating oxide crystals in carbon powder. Further, the stoichiometric amount of oxide ions can be calculated from the mass of oxygen crystals.

The “compound having a spinel structure represented by ZnGa₂O₄” means a compound showing the pattern of No. 38-1240 of the JCPDS card in the X-ray diffraction. As for the crystal structure represented by ZnGa₂O₄, the stoichiometric ratio may be shifted as long as it shows the pattern of the JCPDS card No. 38-1240 in the X-ray diffraction. That is, it may be ZnGa₂O_{4-d}. It is preferred that the amount of oxygen deficiency d be in the range of 3×10⁻⁵ to 3×10⁻¹. d can be adjusted by sintering conditions, atmosphere at the time of sintering, heating and cooling or the like. Further, it can be adjusted by conducting a reduction treatment or an oxidation treatment after sintering.

In the oxide sintered body of the invention, it is preferred that the atomic ratio of Ga to the total of In, Ga and Zn satisfy the following formula (1) and that the atomic ratio of Zn relative to this total satisfy the following formula (2):

0.20<Ga/(In+Ga+Zn)<0.49 (1)

0.10<Zn/(In+Ga+Zn)<0.30 (2)

As for the formula (1), if the atomic ratio of Ga exceeds 0.20, a sintered body comprising the above-mentioned compound having a spinel structure represented by ZnGa₂O₄ can be obtained easily. Further, when the resulting thin film is used in a thin film transistor (TFT), uniformity or reproducibility of TFT properties can be improved.

On the other hand, if the atomic ratio of Ga is less than 0.49, the density of the oxide sintered body can be increased easily and the resistance of the oxide sintered body can be lowered easily.

The atomic ratio [Ga/(In+Ga+Zn)] of Ga is preferably 0.25 or more and 0.48 or less, further preferably 0.35 or more and 0.45 or less, with 0.37 or more and 0.43 or less being particularly preferable.

As for the above-mentioned formula (2), if the atomic ratio of Zn exceeds 0.10, the density of the oxide sintered body may be increased easily, and the resistance of the oxide sintered body may be lowered easily. Further, since the crystallization temperature becomes high, when an amorphous oxide semiconductor film is formed, the amorphous state of the film is stabilized. If the atomic ratio of Zn exceeds 0.10, fine crystals may hardly be generated in the amorphous oxide semiconductor film. Further, when conducting wet etching, residues are hardly remained.

On the other hand, when the atomic ratio of Zn is less than 0.30, a sintered body containing the above-mentioned crystal form can be obtained easily. Further, by using the resulting thin film, uniformity or reproducibility of the TFT properties can be improved.

The atomic ratio [Zn/(In+Ga+Zn)] of Zn is preferably 0.15 or more and 0.25 or less, further preferably 0.17 or more and 0.23 or less.

The atomic ratio [In/(In+Ga+Zn)] of In is preferably larger than 0.20 and less than 0.55. If the atomic ratio of In exceeds 0.20, a sintered body containing the above-mentioned crystal form tends to be obtained easily. Further, by using the resulting thin film, uniformity or reproducibility of TFT properties can be improved.

On the other hand, if the atomic ratio of In is less than 0.55, the density of the oxide sintered body can be increased easily and the resistance can be lowered easily.

The atomic ratio of In [In/(In+Ga+Zn)] is preferably 0.25 or more and 0.50 or less, further preferably 0.35 or more and 0.45 or less, with 0.37 or more and 0.43 or less being particularly preferable.

As compared with ITO or the like, the oxide sintered body satisfying the above-mentioned range has a small content of In. Therefore, as compared with a target containing a large amount of In such as ITO, generation of nodules at the time of sputtering is significantly reduced. Further, a decrease in yield or the like due to particles generated by abnormal discharge caused by nodules when fabricating a thin film transistor is also small.

When an oxygen pressure applied during film formation is required to be decreased, it is preferred that the atomic ratio [In/(In+Ga)] of In relative to the total of In and Ga be 0.59 or less.

In the oxide sintered body of the invention, it is preferred that one of the compound having a bixbyite structure represented by In₂O₃ and the compound having a spinel structure represented by ZnGa₂O₄ be the first (primary) component and the other be the second (sub) component. Due to the presence of these compounds as the first component or the second component, the advantageous effects of the invention (lowering in resistivity of a sintered body, improvement in mobility of a TFT, uniformity, reproducibility or the like of TFT properties) can be developed more easily.

Whether the component is the primary component or the sub component is judged by comparing the maximum peak of each component in the X-ray diffraction. Specifically, the height of the maximum peak of each component in the X-ray diffraction is compared, and the component of which the peak height is the highest is defined as the first component and the component of which the peak height is the second highest is defined as the second component. The same is applied to the third and further components.

In the sputtering target of the invention, the height of the maximum peak in the X-ray diffraction of the compound having a crystal structure represented by β-Ga₂O₃ is preferably half or less, further preferably a tenth or less, of the height of the maximum peak of the compound having a bixbyite structure represented by In₂O₃. It is particularly preferred that the maximum peak height of the compound having a crystal structure represented by β-Ga₂O₃ cannot be confirmed by the X-ray diffraction (the case where the height of the maximum peak of the compound having a crystal structure represented by β-Ga₂O₃ be a hundredth is defined as the case where it is impossible to confirm by the X-ray diffraction). If the amount of the compound having a crystal structure represented by β-Ga₂O₃ is small, an increase in target resistance or generation of abnormal discharge can be suppressed.

Similarly, the height of the maximum peak in the X-ray diffraction of the compound having a homologous crystal structure represented by In₂Ga₂ZnO₇ or InGaZnO₄ is preferably half or less, further preferably a tenth or less, of the height of the maximum peak of the compound having a crystal structure represented by In₂O₃. It is particularly preferred that the maximum peak height of the compound having a homologous crystal structure represented by In₂Ga₂ZnO₇ or InGaZnO₄ cannot be confirmed by the X-ray diffraction. For example, if the maximum peak height of the compound having a homologous crystal structure represented by In₂Ga₂ZnO₇ or InGaZnO₄ is a hundredth or less of the maximum peak height of the compound having a crystal structure represented by In₂O₃, it is impossible to confirm by the X-ray diffraction. If the amount of the compound having a homologous crystal structure is large, when sintering is conducted in an oxidation atmosphere, a problem that a reduction treatment is required or the like may occur.

In the X-ray diffraction, the ratio (I(ZnGa₂O₄)/I(In₂O₃) of the maximum peak intensity (I(In₂O₃)) of a compound having a bixbyite structure represented by In₂O₃ and the maximum peak intensity (I(ZnGa₂O₄) of a compound having a spinel structure represented by ZnGa₂O₄ is preferably 0.80 or more and 1.25 or less. The fact that the ratio of the maximum peak intensity is within in the above-mentioned range means that the sputtering target contains a compound having a bixbyite structure represented by In₂O₃ and a spinel compound represented by ZnGa₂O₄ in almost equal amounts. When these conditions are satisfied, the advantageous effects of the invention tend to be developed more easily.

It is more preferred that the above-mentioned maximum peak intensity ratio be 0.90 or more and 1.10 or less, with 0.95 or more and 1.05 or less being particularly preferable. The maximum peak intensity ratio of 0.99 or more and 1.05 or less is further preferable.

Meanwhile, the maximum peak intensity in the X-ray diffraction means the peak height of the highest peak (this peak may often be referred to as the “main peak”). The attribution of the peak is judged by comparing the pattern of the JCPDS card. If the patterns are coincident, the peak may be shifted. The maximum peak intensity (I(In₂O₃)) of a compound having a bixbyite structure represented by In₂O₃ is normally confirmed at around 30 to 31° and the maximum peak intensity of a compound having a spinel structure represented by ZnGa₂O₄ is normally confirmed at around 35 to 36°.

The shift in peak position means a change in lattice constant (a), and a is preferably 10.05 or more and less than 10.10. It is expected that, if a is less than 10.10, the inter-atomic distance/becomes small, whereby the mobility is increased. However, if a is less than 10.05, distortion of the structure becomes large and symmetry is deteriorated, and as a result, the mobility may be lowered due to scattering.

If the maximum peaks are overlapped, it is possible to calculate the maximum peak from other peaks. Specifically, the maximum peak can be obtained by counting backwardly the intensity of a peak other than the maximum peak by using the intensity ratio data stated in ICDD (International Center for Diffraction Data).

It is preferred that the oxide sintered body of the invention contain a composite oxide containing In, Ga and Zn and having an In-rich phase and a Ga-rich phase. Further, the oxide sintered body in which the In-rich phase has continuity is preferable. It is further preferred that the oxide sintered body of the invention be a sea-island structure in which a Ga-rich phase (island) is present in an In-rich phase (sea). If the In-rich phase is continuous, since the conductivity of the In₂O₃ structure is maintained, the resistance of the target can be lowered.

Here, the In-rich phase means a phase which has a larger indium content as compared with that in the surrounding. At the same time, the Ga-rich phase means a phase which has a large gallium content as compared with that in the surrounding. Being whether an In-rich phase or a Ga-rich phase can be confirmed by an X-ray microanalyzer (Electron Probe Micro Analysis) (EPMA).

The particle size in each phase is preferably 200 μm or less on average, preferably 100 μm or less on average, further preferably 50 μm or less on average, with a particle size of 20 μm or less on average being particularly preferable in respect of stable sputtering. Although no lowest limit is imposed on the particle size of each phase, the particle size is normally 0.1 μm or less.

It is preferable that the In-rich phase have a small oxygen content than that in the surrounding phase. The fact that the oxygen content of the In-rich phase is lower than that in the surrounding phase can be confirmed by EPMA.

In the invention, it is possible to obtain an oxide sintered body having a relative density of 90% or more, a resistivity measured by the four probe method of 50 mΩcm or less and the number of black spots on the surface of 0.1/cm² or less.

If the relative density is 90% or more, the resistance of an oxide sintered body is lowered, and the transverse rupture strength is increased. The relative density is preferably 95% or more, further preferably 98% or more, with 99% or more being particularly preferable.

The relative density is a density which is calculated relative to the theoretical density which is calculated from the weighted average. The density which is calculated from the weighted average of the density of each raw material is a theoretical density, which is taken as 100%.

If the resistivity of the oxide sintered body is 50 mΩcm or less, targets are less likely to be cracked during sputtering. Further, continuous stability of sputtering is improved, whereby occurrence of abnormal discharge becomes less frequent. The resistivity is preferably 30 mΩcm or less, more preferably 20 mΩcm or less, further preferably 10 mΩcm or less.

The resistivity is a value measured by the four probe method by means of a resistivity meter.

If the number of black spots on the surface of the oxide sintered body exceeds 0.1/cm², particles may be generated during sputtering, nodules may be generated and abnormal discharge may occur more frequently. If these phenomena occur, lowering in yield or lowering in reproducibility or uniformity may occur when a TFT is fabricated. The number of black spots is more preferably 0.01/cm² or less, further preferably 0.001/cm² or less.

Meanwhile, the number of black spots on the surface is obtained by dividing the number of black spots countered visually under north window day light by the observed total area.

The oxide sintered body of the invention is preferably an oxide sintered body which further contain a positive tetravalent element X and in which the atomic ratio of X relative to the total of In, Ga, Zn and X satisfies the following formula (3):

0.0001<X/(In+Ga+Zn+X)<0.05 (3)

If the atomic ratio of X exceeds 0.0001, the advantageous effects obtained by adding a positive tetravalent element X are developed, and it is expected that the relative density of the oxide sintered body can be improved or the resistance can be lowered. The atomic ratio is preferably 0.0003 or more, with 0.0005 or more being particularly preferable.

On the other hand, if the atomic ratio of X is less than 0.05, a compound having a bixbyite structure represented by In₂O₃ and a compound having a spinel structure represented by ZnGa₂O₄ are easily obtained, and as a result, the properties of the invention can be obtained easily. The atomic ratio is preferably 0.04 or less, with 0.03 or less being particularly preferable.

By adding X, when forming a thin film transistor, there is a small possibility that a lower oxide of a positive tetravalent element may be generated, and hence the transistor properties may be lowered. Further, possibility is small that un-uniformity in properties due to a change in structure occurs in the thickness direction of a target.

If the atomic ratio of X is 0.05 or more, a lower oxide of X may be generated excessively, whereby the oxide sintered body may have a higher resistance. Further, when fabricating a transistor, the mobility may be lowered, or other problems may also occur.

In the invention, a positive tetravalent element is an element which can take positive tetravalency. Examples of the positive tetravalent element X include Sn, Ge, Si, C, Pb, Ti, Zr, Hf, V, Nb, Ta, Mo, W, Mn, Tc, Re, Fe, Ru, Os, Ir, Pd, Pt, Ce, Pr, Tb, Se and Te.

In respect of an increase in density or control of specific resistance of an oxide sintered body, Sn, Ge, Si, Ti, Zr, Hf, V, Nb, Ta, Mo, W, Mn and Ce are preferable. Sn, Ge, Si, Ti, Zr and Hf are further preferable, and Sn, Ge, Si and Zr are more preferable, with Sn being particularly preferable.

In order to improve uniformity or reproducibility of a thin film transistor having a thin film formed by using an oxide sintered body, Sn, Ge, Si and Zr are preferable. Sn and Zr are further preferable, with Sn being particularly preferable.

In the invention, it is preferred that X be at least one selected from the group consisting of Sn, Ge, Zr, Hf, Ti, Si, Mo and W.

In the invention, it is preferred that an Sn element be contained in the crystal structure of a compound having a bixbyite structure represented by In₂O₃. As a result, effects that the resistivity of an oxide sintered body tends to be lowered can be obtained. Further, presence of Sn in a crystal structure represented by In₂O₃ can be confirmed by the measurement of EPMA.

In the oxide sintered body, the number of aggregated tin oxide particles each having a diameter of 10 μm or more is preferably 2.5 or less per 1.00 mm². Inclusion of the aggregated tin oxide particles in this amount can suppress occurrence of abnormal discharge due to aggregated particles of tin oxide.

In the invention, within a range which does not impair the advantageous effects of the invention, other elements than In, Ga, Zn and a tetravalent element X; Al, Ag, Cu, Sc, Y or the like, for example, may be contained.

However, in the invention, metal elements contained in an oxide sintered body may substantially consist of In, Ga and Zn or In, Ga, Zn and X. Meanwhile, the “substantially” means that other elements than impurities which are inevitably mixed in from a raw material, a production process or the like are not contained.

The oxide sintered body of the invention is obtained by sintering a shaped body formed of a raw material containing indium oxide powder, gallium oxide powder, zinc oxide powder, and if necessary, an oxide of a positive tetravalent element X or an oxide of other metal elements at 1160 to 1380° C. for 1 to 80 hours, for example. Hereinafter, a detailed explanation will be given below.

As for the powder of each oxide as the raw material, the specific surface area thereof is preferably 2 to 16 m²/g. The median diameter is preferably 0.1 to 3 μm. The purity of each raw material powder is normally 99.9% (3N) or more, preferably 99.99% (4N) or more, further preferably 99.995% or more, with 99.999% (5N) or more being particularly preferable. If the purity of each raw material powder is less than 99.9% (3N), semiconductor properties may be lowered due to the presence of impurities, defective appearance such as unevenness in color or spots may be occurred, whereby reliability may be lowered.

As the raw material, a composite oxide such as an In—Zn oxide, an In—Ga oxide or a Ga—Zn oxide may be used. In particular, use of an In—Zn oxide or a Ga—Zn oxide is preferable since evaporation of Zn can be suppressed. Further, use of In₂O₃ powder and ZnGa₂O₃ powder as the raw material is more preferable, since the sintered body of the invention can be obtained easily, and evaporation of Zn can be suppressed.

The mixture of the raw material powder is mixed and pulverized by means of a wet medium stirring mill, for example. At this time, it is preferred that pulverization be conducted such that the specific surface area after pulverizing be increased by 1.5 to 2.5 m²/g as compared with that of the raw material mixed powder or such that the average median diameter after pulverization become 0.6 to 1 μm. By using the raw material powder prepared in this manner, it is possible to obtain a high density oxide sintered body without the need of conducting pre-sintering. Further, a reduction process becomes also unnecessary.

If an increase in the specific surface area of the raw material mixture powder is less than 1.0 m²/g or the average median diameter of the raw material mixture powder exceeds 1 μm, sintering density may not be sufficiently increased. On the other hand, an increase in the specific surface area of the raw material mixture powder exceeds 3.0 m²/g or the average median diameter after pulverization is less than 0.6 μm, the amount of contamination (impurities mixed in) from a pulverizer or the like during pulverization may be increased.

Here, the specific surface area of each powder is a value measured by the BET method. The median diameter of the grain distribution of each powder is a value measured by a particle size analyzer. These values can be adjusted by pulverizing powder by the dry pulverizing method, the wet pulverizing method or the like.

When pre-firing is conducted, it is preferred that the mixture powder be maintained in an electric furnace or the like at 800 to 1050° C. for 1 to 24 hours in an atmosphere or an oxygen atmosphere. The pre-fired powder is input in an attritor together with zirconia beads and finely pulverized at a revolution of 50 to 1,000 rpm for 1 to 10 hours. The resulting finely pulverized product preferably has an average grain diameter (D50) of 0.1 to 0.7 μm, more preferably 0.2 to 0.6 μm, with 0.3 to 0.55 μm being particularly preferable.

The mixture powder obtained in the mixing and pulverization step is dried by means of a spray drier or the like, followed by shaping. Shaping can be conducted by a known method, such as pressure shaping and cold isostatic pressing.

Sintering is normally conducted by heating at 1100 to 1380° C. for 1 to 100 hours. By conducting sintering at 1100° C. or higher, the relative density of the oxide sintered body is increased, whereby the resistivity is lowered. If sintering is conducted at a temperature of 1380° C. or less, evaporation of zinc can be suppressed easily, and possibility that the composition of a sintered body is changed or voids are generated in the sintered body by evaporation is small. Further, risk that a furnace is damaged becomes low.

By prolonging the sintering time to 1 hour or longer, dispersion due to insufficient sintering can be prevented. Further, by prolonging the sintering time to 100 hours or shorter, distortion or deformation after sintering can be prevented.

In order to produce an oxide sintered body comprising a compound having a crystal structure represented by In₂O₃ and a compound having a crystal structure represented by ZnGa₂O₄, it is preferable to conduct sintering at 1160 to 1380° C. for 1 to 80 hours, further preferably 1220 to 1340° C. for 1.5 to 50 hours, with 1220 to 1340° C. for 2 to 20 hours being particularly preferable.

In the invention, it is preferred that the shaped body be heated at 700 to 900° C. for 5 to 8 hours before sintering, and subsequently, be sintered at the above-mentioned temperature (two-stage sintering). Further, until the temperature is elevated to 500 to 900° C., the heating rate is less than 1° C./min. Thereafter, the heating time is switched to 1° C./min or higher, and the shaped body is heated to the above-mentioned sintering temperature to conduct sintering. By this procedure, un-uniformity in properties due to the difference in thermal history generated in the parts of the sintered body or generation of cracks can be prevented. Further, generation of a homologous structure can be suppressed.

Further, sintering is conducted in the presence of oxygen. For example, sintering is conducted in the oxygen atmosphere by circulating oxygen or under oxygen pressure. The preferable oxygen pressure is 0.5 to 5 atmospheric pressures, and further preferably 1 to 3 atmospheric pressures. By this oxygen pressure, evaporation of zinc can be suppressed, whereby a sintered body without voids can be obtained. Further, the nitrogen content in the target can be reduced.

Since the thus prepared sintered body has a high density, generation of nodules or particles during use is small, an oxide semiconductor film having excellent film properties can be obtained.

The cooling rate after sintering is preferably 0.5° C./min or more, more preferably 2° C./min or more, with 3° C./min or more being further preferable. If the cooling rate is equal to or higher than 0.5° C./min, suppression of precipitation of stable crystals at an intermediate temperature can be expected. Further, the cooling rate after sintering is preferably 50° C./min or less. If the cooling rate exceeds 50° C./min, uniform cooling may not be conducted, whereby unevenness in properties may occur.

The sputtering target can be produced by subjecting the sintered oxide body obtained by sintering to a processing such as polishing. Specifically, it is preferred that a sintered body be polished by means of a plane grinder to allow the surface roughness Ra to be 5 μm or less. Further, by subjecting the sputtering surface of the target to mirror finishing, the average surface Ra may be allowed to be 1000 Å or less.

For mirror finishing (polishing), a known polishing technology such as mechanical polishing, chemical polishing and mechano-chemical polishing (combination of mechanical polishing and chemical polishing) can be used. For example, it can be obtained by polishing by means of a fixed abrasive polisher (polishing liquid: water) to attain a roughness of #2000 or more, or can be obtained by a process in which, after lapping by a free abrasive lap (polisher: SiC paste or the like), lapping is conducted by using diamond paste as a polisher instead of the SiC paste. There are no specific restrictions on these polishing methods.

For target cleaning, air blowing, washing with running water or the like can be used. When foreign matters are removed by air blowing, foreign matters can be removed more effectively by air intake by means of a dust collector from the side opposite to the air blow nozzle.

In addition to air blowing or washing with running water, ultrasonic cleaning or the like can also be conducted. In ultrasonic cleaning, it is effective to conduct multiplex oscillation within a frequency range of 25 to 300 kHz. For example, it is preferable to perform ultrasonic cleaning every 25 kHz in a frequency range of 25 to 300 kHz by subjecting 12 kinds of frequency to multiplex oscillation.

In the invention, a reduction treatment after sintering is not required. However, reduction may be conducted in order to obtain a uniform resistivity of a sintered body as a whole. As the reduction treatment, reduction such as a method using a reductive gas, vacuum firing, reduction by an inactive gas or the like can be given, for example.

In the case of a reduction treatment by using a reductive gas, hydrogen, methane, carbon monoxide or a mixture of these gases and oxygen can be used. In the case of a reduction treatment by firing in an inactive gas, nitrogen, argon, a mixed gas of these gases with oxygen or the like can be used. The temperature at the time of a reduction treatment is normally 100 to 800° C., preferably 200 to 800° C. Further, a reduction treatment is normally 0.01 to 10 hours, and preferably 0.05 to 5 hours.

The particle size of each compound in the oxide sintered body of the invention is normally 200 μm or less, preferably 20 μm or less, further preferably 10 μm or less, with 5 μm or less being particularly preferable. The particle size is an average particle size measured by EPMA. Although there is no lowest limit being imposed on the particle size, it is normally 0.1 μm or more.

The particle size can be controlled by adjusting the amount ratio of powder of each oxide as the raw material or the particle size, purity, heating time, sintering time, sintering temperature, sintering atmosphere and cooling time of the raw material powder. If the particle size of the compound is larger than 20 μm, nodules may be generated at the time of sputtering. If the particle size is larger than 200 μm, the surface of the target becomes uneven, whereby abnormal discharge at the time of film formation may occur easily.

The transverse rupture strength of the sputtering target is preferably 8 kg/mm² or more, more preferably 10 kg/mm² or more, with 12 kg/mm² or more being particularly preferable. Since a target may be broken since a load is imposed on the transportation or installation of a target, a target is required to have a certain degree or more of transverse rupture strength. If the transverse rupture strength is less than 8 kg/mm², it cannot be used as a target. The transverse rupture strength of a target can be measured in accordance with JIS R 1601.

The range of the dispersion of positive elements other than zinc in the target is preferably within 0.5%. Further, the range of variation in density in the target is preferably within 3%.

It is preferred that the surface roughness Ra of the target be 0.5 μm or less and have a grinding surface having no orientation. If Ra is larger than 0.5 μm or the grinding surface has orientation, abnormal discharge may occur or particles may be generated.

It is preferred that the number of pinholes having a Ferret diameter of 2 μm or more be 50/mm² or less, more preferably 20/mm² or less, with 5/mm² being further preferable. If the number of pinholes having a Ferret diameter of 2 μm or more is larger than 50/mm², abnormal discharge occurs frequently from the initial stage to the final stage of the use of the target. Further, the smoothness of the resulting sputtering film tends to be lowered. If the number of pinholes having a Ferret diameter of 2 μm or more inside of the sintered body is 5/mm² or less, abnormal discharge from the initial stage to the final stage of the use of the target can be suppressed, and the resulting sputtering film is very smooth.

Here, the Ferret diameter means a distance between two parallel lines which sandwich a particle and run in a certain direction, when a pinhole is taken as a particle. The Ferret diameter can be measured by observing an SEM image with a magnification of 100 times.

In the oxide sintered body of the invention, the nitrogen content is preferably 5 ppm (atom) or less. By allowing the nitrogen content to be 5 ppm or less, when an oxide thin film is formed by sputtering, the nitrogen content in the thin film is lowered, whereby reliability and uniformity of a TFT can be improved when a thin film is used as a thin film transistor (TFT).

If the nitrogen content of the oxide sintered body exceeds 5 ppm, not only occurrence of the resulting target at the time of sputtering may be suppressed sufficiently and the amount of the gas absorbed on the target surface may not be sufficiently suppressed, but also nitrogen and indium in the target may be reacted at the time of sputtering to generate black indium nitride (InN), and the black indium nitride may be mixed in the semiconductor film to lower the yield. The reason therefor is assumed to be as follows. If the nitrogen atoms are contained in an amount exceeding 5 ppm, the nitrogen atoms become mobile ions, and the mobile ions are gathered in the interface of the semiconductor due to gate voltage stress to form traps, or nitrogen serves as a donor to lower the performance.

In order to allow the nitrogen content to be 5 ppm (atom) or less, it is preferred that sintering be conducted in a non-nitrogen atmosphere (oxygen atmosphere, for example) and no reduction be conducted in a nitrogen-containing atmosphere. Further, it is more preferred that sintering be conducted in the flow of oxygen since remaining nitrogen is released.

The nitrogen content in the sintered body can be measured by a total trace nitrogen analyzer (TN). The total trace nitrogen analyzer is used for measurement of only nitrogen (N) or nitrogen (N) and carbon (C) in the elemental analysis, and is used to obtain the amount of nitrogen or the amount of nitrogen and the amount of carbon.

In the TN, a nitrogen-containing inorganic matter or a nitrogen-containing organic matter are decomposed in the presence of a catalyst, and N is converted into nitrogen monoxide (NO), and this NO gas is subjected to a vapor phase reaction with ozone, and light is emitted by chemical emission, and N is quantitatively analyzed based on this emission intensity.

The resulting target is bonded to a backing plate, and mounted in various film-forming apparatus. Examples of the film-forming method include the sputtering method, the PLD (Pulse Laser Deposition Method), the vacuum vapor deposition method, the ion plating method or the like.

By forming a film by using the target of the invention, an amorphous oxide film can be obtained. This film can be preferably used as a constituting element of a semiconductor device such as a thin film transistor.

An example in which the oxide film obtained in the invention is applied to a thin film transistor will be explained below.

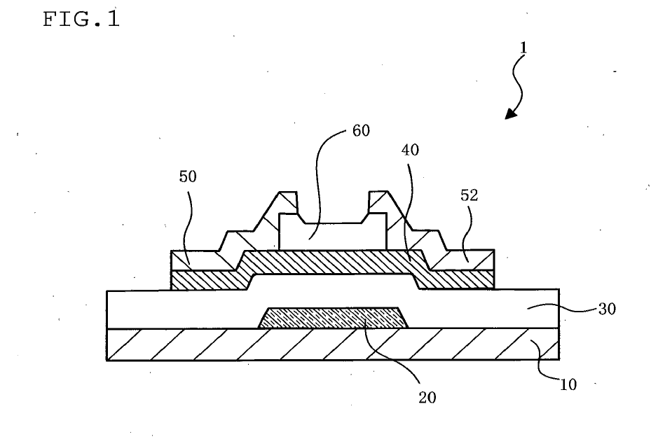

FIG. 1 is a schematic cross-sectional view showing one embodiment of the thin film transistor.

A thin film transistor 1 has a gate electrode 20 between a substrate 10 and a gate-insulating film 30. On the gate-insulting film 30, a semiconductor film 40 is stacked as an activating layer (channel layer). On the top of the semiconductor film 40, an etch stopper 60 is formed. A source electrode 50 and a drain electrode 52 are respectively provided such that the vicinity of the end part of the semiconductor film 40 and the vicinity of the etch stopper 60 are covered.

A film obtained by the sputtering target formed of the oxide sintered body of the invention can be used as the semiconductor film 40 of the thin film transistor 1. As mentioned above, film formation is conducted by using a sputtering target. For example, it is conducted by the film formation method such as sputtering.

The thin film transistor 1 shown in FIG. 1 is the so-called channel stopper type thin film transistor. The thin film transistor of the invention is not limited to a channel stopper type thin film transistor, and a device configuration which is known in this technical field can be used. For example, an etch stopper 60 in the thin film transistor 1 may not be formed.

Hereinbelow, components of the thin film transistor will be explained.

### 1. Substrate

There are no specific restrictions on the substrate, and substrates known in this technical field can be used. For example, glass substrates such as alkaline silicate glass, non-alkaline glass and quarts glass; resin substrates such as a silicon substrate, acryl, polycarbonate and polyethylene naphthalate (PEN), and polymer film substrates such as polyethylene terephthalate (PET) and polyamide can be used.

### 2. Semiconductor Layer

As mentioned above, a film obtained by using a sputtering target formed of the oxide sintered body of the invention is used. It is preferred that the semiconductor layer be an amorphous film. Due to the amorphous nature, there are advantages that adhesion with an insulating film or a protective layer can be improved or uniform transistor properties can be obtained easily in a large area. Here, whether a semiconductor layer is an amorphous film or not can be confirmed by the X-ray crystal structure analysis. When no clear peak is observed, the film is amorphous.

### 3. Protective Layer

No specific restrictions are imposed on the material for forming a protective layer. A material which is generally used can be arbitrarily selected within a range which does not impair the effects of the invention. For example, SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTI₃, BaTa₂O₆, SrTiO₃ and AlN or the like can be used. Of these, it is preferable to use SiO₂, SiNx, Al₂O₃, Y₂O₃, Hf₂O₃ and CaHfO₃. SiO₂, SiNx, Y₂O₃, Hf₂O₃ and CaHfO₃ are more preferable, with oxides such as SiO₂, Y₂O₃, Hf₂O₃ and CaHfO₃ being particularly preferable. The oxygen number of these oxides may not necessarily coincide with the stoichiometric ratio (for example, it may be SiO₂ or SiOx). Further, SiNx may contain a hydrogen atom.

The protective film may be of a structure in which two or more different insulating layers are stacked.

### 4. Gate Insulating Film

No specific restrictions are imposed on the material for forming a gate insulating film. A material which is generally used can be arbitrarily selected. For example, SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTI₃, BaTa₂O₆, SrTiO₃ and AlN or the like can be used. Of these, it is preferable to use SiO₂, SiNx, Al₂O₃, Y₂O₃, Hf₂O₃ and CaHfO₃. SiO₂, SiNx, Y₂O₃, Hf₂O₃ and CaHfO₃ are more preferable. The oxygen number of these oxides may not necessarily coincide with the stoichiometric ratio (for example, it may be SiO₂ or SiOx). Further, SiNx may contain a hydrogen atom.

The gate insulating film may be of a structure in which two or more different insulating layers are stacked. Further, the gate insulting film may be crystalline, polycrystalline or amorphous. A polycrystalline film or an amorphous film is preferable since it can be manufactured easily on the industrial basis.

Further, as the gate insulating film, an organic insulating film such as poly(4-vinylphenol) (PVP) and parylene. Further, the gate insulting film may have a structure having two or more layers of an inorganic insulting film and an organic insulating film.

### 5. Electrode

No specific restrictions are imposed on the material for forming each electrode such as a gate electrode, a source electrode and a drain electrode, and a known material can be arbitrarily selected.

For example, transparent electrodes such as indium tin oxide (ITO), indium zinc oxide, ZnO and SnO₂ or a metal electrode such as Al, Ag, Cr, Ni, Mo, Au; Ti, Ta and Cu or an alloy containing these can be used.

As for the method for producing a thin film transistor (field effect transistor), each constitution component (layer) of a transistor can be formed by a method known in this technical field.

Specifically, as for the film forming method, a chemical film-forming method such as the spray method, the dipping method and the CVD method and a physical film-forming method such as the sputtering method, the vacuum vapor deposition method, the ion plating method and pulse laser deposition method. Due to easiness in carrier density control or easiness in improvement of film quality, a physical film-forming method is preferably used. A sputtering method is more preferable due to high productivity.

The film thus formed can be patterned by various etching methods.

In the invention, the semiconductor layer can be formed by DC or AC sputtering by using the target formed of the oxide sintered body of the invention. By using DC or AC sputtering, as compared with the case of RF sputtering, damage at the time of film formation can be deceased. In the field effect transistor, improvement in mobility or the like can be expected.

In the invention, after forming a semiconductor layer and a protective layer for a semiconductor, it is preferred that a heat treatment be conducted at 70 to 350° C. If the heat treatment temperature is lower than 70° C., the heat stability or heat resistance of the resulting transistor may be lowered, the mobility may be lowered, the S value may be increased or the threshold voltage may be increased. On the other hand, if the heat treatment temperature is higher than 350° C., it may not possible to use a substrate having no heat resistance or extra cost may be incurred for facilities of a heat treatment.

It is preferred that a heat treatment be conducted under circumstances where an oxygen partial pressure of 10⁻³ Pa or less in an inert gas or be conducted after covering the semiconductor layer with a protective layer. Under the above-mentioned conditions, reproducibility is improved.

In the thin film transistor obtained by the invention, the mobility is preferably 1 cm²/Vs or more, more preferably 3 cm²/Vs or more, with 8 cm²/Vs or more being particularly preferable. If the mobility is smaller than 1 cm²/Vs, the switching rate may be slow and, as a result, the thin film transistor may not be used in a large-area, high-precise display.

The on-off ratio is preferably 10⁶ or more, more preferably 10⁷ or more, with 10⁸ or more being particularly preferable.

### EXAMPLES

### Example 1

### Preparation of an Oxide Sintered Body

As the raw material powder, powder of In₂O₃ (specific surface area: 11 m²/g, purity: 99.99%), Ga₂O₃ (specific surface area: 11 m²/g, purity: 99.99%) and ZnO (specific surface area: 9 m²/g, purity: 99.99%) were used. The raw material was mixed such that the atomic composition ratio shown in Table 1 was attained. The resulting mixture was mixed by means of a super mixer for 4 minutes. Mixture was conducted in the air with a revolution of 3000 rpm.

The resulting mixture powder was retained in an electric furnace in an atmosphere at 1000° C. for 5 hours to conduct pre-firing. The resulting pre-fired powder was put into an attritor together with zirconia beads, and the resultant was finely pulverized at a revolution of 300 rpm for 3 hours. After the pulverization, the raw material powder had an average particle size (D50) of 0.55 μm.

To the thus finely pulverized raw material powder, water was added such that slurry having a solid matter content of 50 wt % could be obtained. This slurry was granulated in a granulator. The inlet temperature and the outlet temperature of the granulator were set to 200° C. and 120° C., respectively.

The granulated powder was subjected to press shaping at a contact pressure of 450 kgf/cm² by holding for 60 seconds. Then, the powder was shaped at a contact pressure of 1800 kgf/cm² by holding for 90 seconds by cold isostatic pressing.

Then, in the oxygen atmosphere (oxygen pressurization: 2 atmospheric pressures), the shaped product was heated to 800° C. in an electric furnace at a heating rate of 0.5° C./min, and retained at 800° C. for 5 hours. Thereafter, the shaped product was heated to 1300° C. at a heating rate of 1.0° C./min, and retained at 1300° C. for 20 hours.

Thereafter, the temperature was lowered by cooling the furnace (cooling rate was 0.5° C./min or more) to obtain a sintered body.

In this example, a reduction treatment by a heat treatment or the like in the absence of oxygen was not conducted.

The resulting sintered body was pulverized and analyzed by means of an ICP atomic emission spectrometer (manufactured by Shimadzu Corporation), and it was found that the atomic ratio of the contained metal elements (In:Ga:Zn) was 40:40:20.

The properties and physical properties of the sintered body are shown in Table 1. Evaluation was conducted by the following method.

### (1) Relative Density

Relative density was measured by the following formula based on the theoretical density calculated from the density of the raw material powder and the density of the sintered body measured by the Archimedian method.

Relative density=(Density measured by the Archimedian method)/(Theoretical density)×100(%)

### (2) Resistivity

Resistivity was measured by the four probe method (JIS R1637) using a resistivity meter (Loresta, manufactured by Mitsubishi Chemical Corporation). The average value of the resistivity values of ten points is taken as the value of resistivity.

### (3) Density of Black Spots on the Surface

10 targets were prepared. The number of black spots counted by naked eyes in the north window day light was divided by the total area.

### (4) Transverse Rupture Strength (Bending Strength)

Transverse rupture strength was measured according to JIS R1601 by means of a transverse rupture testing machine (Autograph, manufactured by Shimadzu Corporation).

### (5) Cracks at the Time of Sintering

5 targets (sintered bodies) were observed with the naked eyes immediately after the sintering to confirm the occurrence of cracks.

### (6) X-Ray Diffraction Measurement (XRD)

Apparatus: Ultima-III, manufactured by Rigaku Corporation

X rays: Cu-Kα rays (wavelength: 1.5406 Å, monochromized by means of a graphite monochrometer)

2θ-θ reflection method, continuous scanning (1.0°/min)

Sampling interval: 0.02°

Slit DS, SS: ⅔°, RS: 0.6 mm

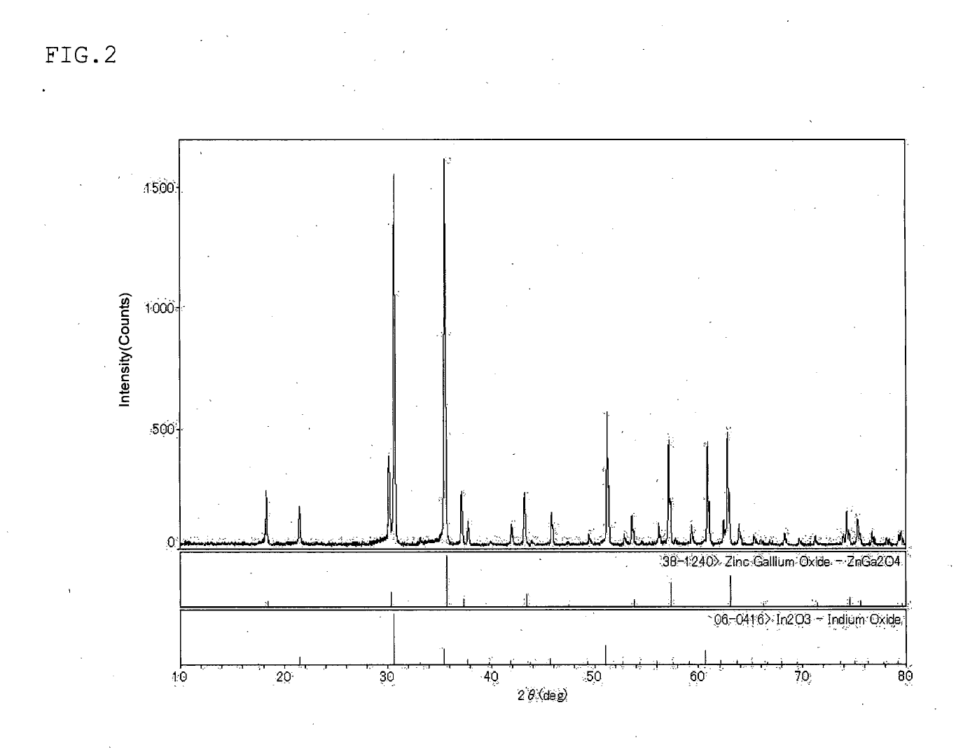

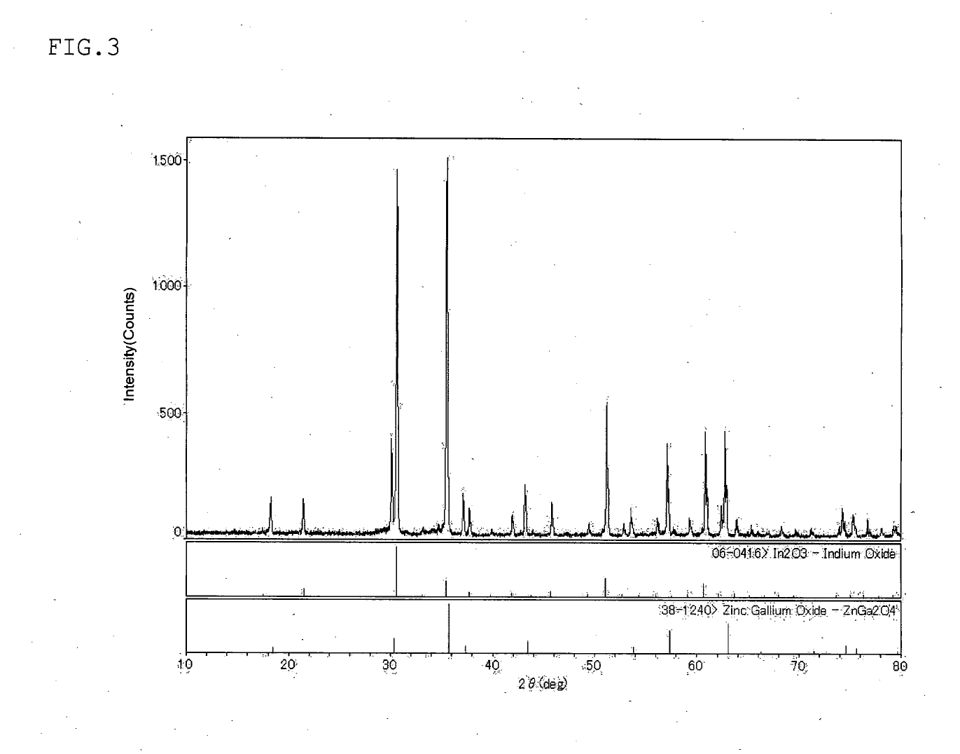

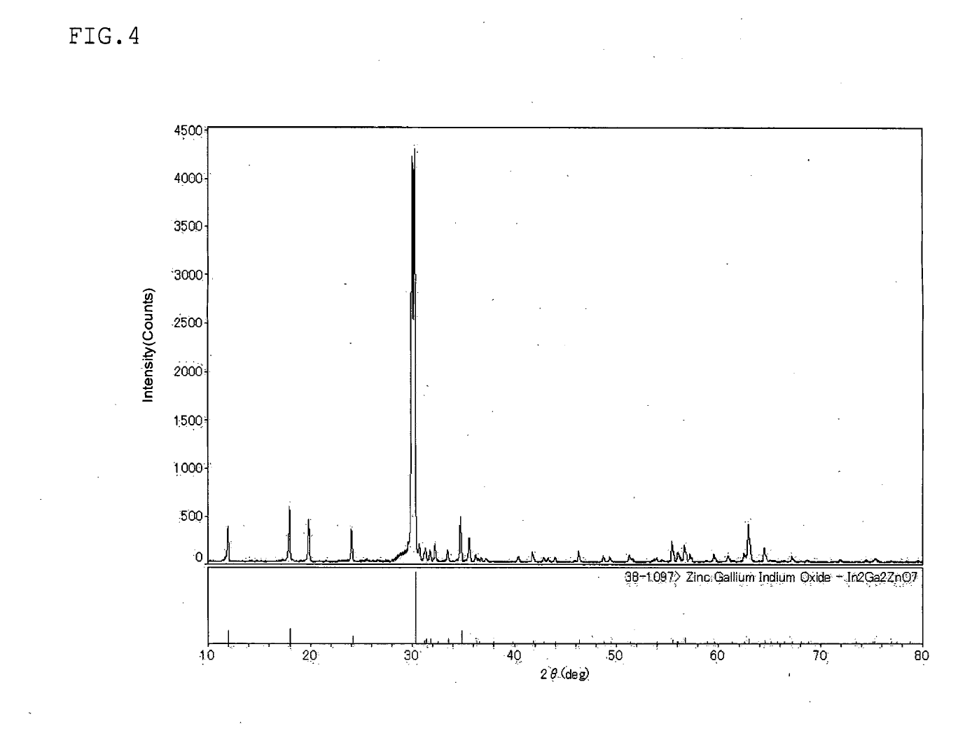

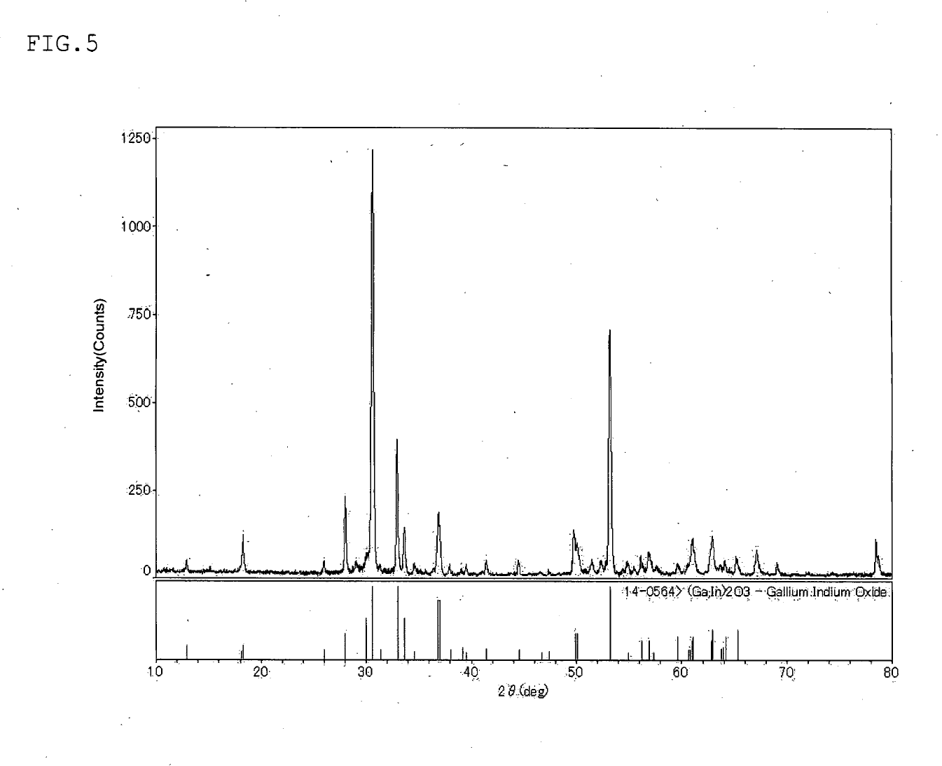

FIGS. 2 to 5 show the X-ray diffraction (XRD) data of the surfaces of the sintered bodies prepared in Examples 1 and 2 and Comparative Examples 1 and 2.

The ratio (I(ZnGa₂O₄)/I(In₂O₃)) of the maximum peak intensity (I(In₂O₃)) in the X-ray diffraction (XRD) of the compound having a bixbyite structure represented by In₂O₃ and the maximum peak intensity (I(ZnGa₂O₄) of the compound having a spinet structure represented by ZnGa₂O₄ was 1.04 in Example 1 and 1.03 in Example 2. A compound having a homologous crystal structure represented by In₂Ga₂ZnO₇ or InGaZnO₄ was not confirmed.

Further, by the measurement of EPMA, presence of an In-rich phase and a Ga-rich phase was confirmed. Further, it was confirmed that the In-rich phase had a lower oxygen content than that in other layers.

Further, the nitrogen content in the sintered body measured by a total trace nitrogen analyzer (TN) was 5 ppm or less.

TABLE 1

| | | | Examples | | Com. Examples | |
|---|---|---|---|---|---|---|
| | | | 1 | 2 | 1 | 2 |
| Raw | Specific surface | In₂O₃ | 11 | 11 | 11 | 11 |
| material | area (m²/g) | Ga₂O₃ | 11 | 11 | 11 | 11 |
| | | ZnO | 9 | 9 | 9 | 9 |
| Sintered | Composition ratio | In/(In + Ga + Zn) | 0.4 | 0.4 | 0.4 | 0.4 |
| body | of elements | Ga/(In + Ga + Zn) | 0.4 | 0.4 | 0.4 | 0.4 |
| | (Atomic ratio) | Zn/(In + Ga + Zn) | 0.2 | 0.2 | 0.2 | 0.2 |
| | Sintering | Sintering | 1300 | 1300 | 1400 | 1500 |
| | conditions | temperature (° C.) | | | | |
| | | Sintering time(Hr) | 20 | 2 | 2 | 2 |
| | Crystal system of | In₂O₃ | \textcircled{2} | \textcircled{2} | | |
| | compound *¹ | ZnGa₂O₄ | \textcircled{1} | \textcircled{1} | | |
| | | GaInO₃ | | | | |
| | | InGaZnO₄ | | | | |
| | | In₂Ga₂ZnO₇ | | | \textcircled{1} | |
| | | (Ga,In)₂O₃ | | | | \textcircled{1} |
| | | Others | | | | |

| | | | | | |
|---|---|---|---|---|---|
| Physical | Relative density (%) | 96 | 91 | 89 | 88 |
| properties of | Resistivity (mΩcm) | 3 | 9 | 53 | 3100 |
| sintered body | Density of black spots on the | 0 | 0 | 1 | 3 |
| | surface (number/cm²) | | | | |
| | Transverse rupture strength (kg/mm²) | 13.2 | 12.4 | 8.3 | 7.2 |
| | Occurrence of cracking during sintering | None | None | Occurred | Occurred |

*¹ The crystal system of the compound was obtained by X-ray diffraction measurement and JCPDS card.
In the table, \textcircled{1} means the primary component and \textcircled{2} means the second component.
Correspondence of the crystal system and the JCPDS card is as follows.
In₂O₃: JCPDS card No. 6-0416
ZnGa₂O₄: JCPDS card No. 38-1240
GaInO₃: JCPDS card No. 21-0334
InGaZnO₄: JCPDS card No. 38-1104
In₂Ga₂ZnO₇: JCPDS card No. 38-1097
(Ga,In)₂O₃: JCPDS card No. 14-0564

### Example 2 and Comparative Examples 1 and 2

A TFT was fabricated and evaluated in the same manner as in Example 1, except that the composition and sintering conditions were changed to those shown in Table 1.

### Example 3

### (A) Preparation of an Oxide Sintered Body

In₂O₃ powder having a specific surface area of 15 m²/g and purity of 99.99%, Ga₂O₃ powder having a specific surface are of 14 m²/g and purity of 99.99% and ZnO powder having a specific surface area of 4 m²/g and purity of 99.99% were compounded, and the resultant was mixed and pulverized by means of a ball mil until the grain size of each raw material powder became 1 μm or less. The thus obtained slurry was taken out, and rapidly dried and granulated by means of a spray drier at a slurry supply speed of 140 ml/min, a hot air temperature of 140° C. and a hot air amount of 8 Nm³/min. The granulated product was shaped at a pressure of 3 tons/cm² by cold isostatic pressing, thereby to obtain a shaped product.

Subsequently, this shaped product was sintered. During the sintering, the temperature was elevated at a rate of 0.5° C./min in the air until it reached 600° C., and thereafter, in the range of 600° C. to 800° C., the temperature was elevated at a rate of 1° C./min while introducing an oxygen gas at a flow rate of 10 L/min. In the temperature range of 800° C. to 1300° C., the temperature was elevated at a rate of 3° C./min. The oxygen pressurization was conducted at 2 atomic pressures. Thereafter, the shaped product was held at 1300° C. for 20 hours, and then cooled at a rate of 1° C./min to obtain a sintered body. A reduction treatment by a heat treatment or the like in the absence of oxygen was not conducted.

Properties and physical properties of the sintered body were evaluated in the same manner as in Example 1. The results are shown in Table 2-5.

### (B) Preparation of a Sputtering Target

A sintered body for a target was cut out of the sintered body as prepared above. The sides of the sintered body for a target were cut by means of a diamond cutter, and the surface was ground by means of a surface grinding machine to obtain a target material having a surface roughness Ra of 5 μm or less.

Subsequently, the surface was subjected to air blow, and then ultrasonic cleaning was conducted for 3 minutes within a frequency range of 25 to 300 kHz by causing 12 kinds of frequency to multiplex oscillation every 25 kHz. Thereafter, the target material was bonded to an oxygen-free copper backing plate by means of indium solder, whereby a target was obtained.

The target had a surface roughness of Ra of 0.5 μm or less and a ground surface having no direction. The average crystal particle size of the sintered body was 10 μm or less. The number of pinholes within the sintered body having a Ferret diameter of 2 μm or more was 5/mm² or less. Variation in relative density in the plane direction of the target was 1% or less and the average number of voids was 800/mm² or less. No black spots were found.

Variation in relative density was measured by cutting 10 arbitral parts of the sintered body and the density thereof was obtained by the Archimedian method. Based on the average value, the maximum value and the minimum value, the variation was obtained by calculating from the following formula.

Variations in relative density=(Maximum−Minimum)/Average×100

The average crystal particle size was evaluated as follows. The sintered body was buried in a resin. The surface of the sintered body was polished using alumina particles (particle size: 0.05 μm), and observed using an X-ray microanalyzer (EPMA) (“JXA-8621 MX” manufactured by JEOL Ltd.) (magnification: ×5000). The maximum diameter of crystal particles observed on the surface of the sintered body within a square range of 30 μm×30 μm was measured. The maximum diameter thus measured was taken as the average crystal grain size.

As for the average number of voids, the sintered body was mirror-polished in an arbitrary direction, and then etched. The texture was observed using a scanning electron microscope (SEM), and the number of voids having a diameter of 1 μm or more per unit area was counted.

By using the thus prepared target, the state of sputtering was evaluated by RF magnetron sputtering and DC magnetron sputtering. The results are shown in Tables 4 and 5. Evaluation was conducted as follows.

### RF Sputtering

### (1) Abnormal Discharge

The frequency of abnormal discharge occurred every 3 hours was measured. The frequency of 5 times or less was evaluated as A, the frequency of 6 times or more and 10 times or less was evaluated as B, the frequency of 11 times or more and 20 times or less is evaluated as C and 21 times or more and 30 times or less was evaluated as D.

### (2) In-Plane Uniformity

The ratio of the maximum value and the minimum value of the specific resistance in the same plane (maximum value/minimum value) was measured. The evaluation was conducted in the following four stages in the order of goodness in uniformity in specific resistance. Specifically, an in-plane uniformity of 1.05 or less was evaluated as A, an in-plane uniformity of larger than 1.05 and 1.10 or less was evaluated as B, an in-plane uniformity of larger than 1.10 and 1.20 or less was evaluated as C and an in-plane uniformity of larger than 1.20 was evaluated as D.

### DC Sputtering

### (1) Abnormal Discharge

The frequency of abnormal discharge occurred within 96 hours was measured.

### (2) Occurrence of Nodules

Occurrence of nodules was evaluated as follows:

A: Almost none B: Slightly occurred C: Occurred D: Frequently occurred E: Film formation was impossible

### (3) Continuous Stability

As for film forming properties, the ratio of the average field effect mobility in the 1^{st} batch and the average field effect mobility in the 20^{th} batch in continuous 20 batches (the 1^{st} batch/the 20^{th} batch) was measured. Evaluation was conducted in the following four stages in the order of goodness in reproducibility of TFT properties. Specifically, a reproducibility of 1.10 or less was evaluated as A, a reproducibility of larger than 1.10 and 1.20 or less was evaluated as B, a reproducibility of larger than 1.20 and 1.50 or less was evaluated as C and a reproducibility of larger than 1.50 was evaluated as D.

### (4) In-Plane Uniformity

The ratio of the maximum value and the minimum value of the specific resistance in the same plane (maximum value/minimum value) was measured. The evaluation was conducted in the following four stages in the order of goodness in uniformity in specific resistance. Specifically, an in-plane uniformity of 1.05 or less was evaluated as A, an in-plane uniformity of larger than 1.05 and is equal to and smaller than 1.10 was evaluated as B, an in-plane uniformity of larger than 1.10 and is equal to and smaller than 1.20 was evaluated as C and an in-plane uniformity of larger than 1.20 was evaluated as D.

### (5) Occurrence of Cracking in the Target

Cracking occurred in 10 sputtering targets (occurrence of cracking in the target) were with the naked eyes observed immediately after the film formation, and presence of cracks was confirmed. A case in which no cracks occurred in all of the 10 targets was evaluated as A, a case in which cracks occurred in one target was evaluated as B and a case in which cracks occurred in two or more cracks was evaluated as D.

### (C) Preparation of a Thin Film Transistor

A channel stopper type thin film transistor shown in FIG. 1 (reverse staggered thin film transistor) was fabricated.

A glass substrate (Corning 1737) was used as a substrate 10. First, on the substrate 10, a 10 nm-thick Mo, an 80 nm-thick Al and a 10 nm-thick Mo were sequentially stacked by the electron beam deposition method. The thus obtained stack was formed into a gate electrode 20 by the photolithographic method and the lift-off method.

On the gate electrode 20 and the substrate 10, a 200 nm-thick SiO₂ film was formed by the TEOS-CVD method to form a gate-insulating layer 30. Although the gate-insulating layer may be formed by the sputtering method, it is preferred that the gate-insulating layer be formed by the CVD method such as the TEOS-CVD method or the PECVD method. If it is formed by the sputtering method, off current may be increased.

Subsequently, by the RF sputtering method, by using the target prepared in (B) above, a 40 nm-thick semiconductor film 40 (channel layer) was formed. On the semiconductor film 40, an SiO₂ film as an etching stopper layer 60 (protective film) was deposited by the sputtering method. The protective film may be formed by the CVD method.

In this example, the input RF power was 200 W. The atmosphere at the time of film formation was a total pressure of 0.4 Pa and a gas flow ratio at this time was Ar:O₂ of 92:8. The substrate temperature was 70° C. The resulting stack of the oxide semiconductor film and the protective film was processed into an appropriate size by the photolithographic method and the etching method.

After the formation of the etching stopper layer 60, a 5 nm-thick Mo film, a 50 nm-thick Al film and a 5 nm-thick Mo film were sequentially stacked. By the photolithographic method and the dry etching method, a source electrode 50 and a drain electrode 52 were formed.

Thereafter, a heat treatment was conducted in the air at 300° C. for 60 minutes, whereby a transistor having a channel length of 10 μm and a channel width of 100 μm was fabricated. In the substrate (TFT panel), total 100 TFTs were arranged at an equal interval (10 lines×10 rows).

The results of evaluating the target and the thin film transistor are shown in Table 2-5. The thin film transistor was evaluated as follows.

(1) Mobility (Field Effect Mobility (μ)) and on-Off Ratio

The field effect mobility (μ) was measured by means of a semiconductor parameter analyzer (Keithley 4200) at room temperature in a light-shielding environment.

### (2) Uniformity in TFT Properties

The ratio of the maximum value and the minimum value of the on current (maximum value/minimum value) at a Vg of 6V in the same panel was measured. The ratio of the maximum value and the minimum value was classified and evaluated according to the following criterion:

Within 1.05: A, within 1.10: B, within 1.20: C, exceeding 1.20: D

### (3) Reproducibility of TFT Properties

The ratio of the average field effect mobility in the first batch and that in the fifth batch (1^{st} batch/5^{th} batch) in the continuous 5 batches was measured. The ratio of the average field effect mobility was classified and evaluated according to the following criterion:

Within 1.10: A, within 1.20: B, within 1.50: C, exceeding 1.50: D

### (4) Yield of TFT

For the panel of continuous 10 batches, driving of 100 TFTs in the same panel (total: 1000 TFTs) was confirmed, and the number of TFTs which were driven was counted. However, the number of TFTs which were not driven due to short circuit was excluded. The number of TFTs which was driven was classified and evaluated according to the following criterion:

999 or more TFTs were driven: A, 995 or more and less than 999 TFTs were driven: B, 990 or more and less than 995 TFTs were driven: C, less than 990 TFTs were driven: D

### Examples 4 to 21 and Comparative Examples 3 to 10

Targets and thin film transistors were formed and evaluated in the same manner as in Example 3, except that the raw material, the composition, the production conditions or the like were changed as shown in Tables 2 and 3. The results are shown in Table 2-5.

As a tin oxide, SN006PB manufactured by Kojundo Chemical Laboratory Co., Ltd. was used. As an oxide of Ge, GE007PB manufactured by Kojundo Chemical Laboratory Co., Ltd. was used. As an oxide of Hf, HF001PB manufactured by Kojundo Chemical Laboratory Co., Ltd. was used. As an oxide of Ti, TI014PB manufactured by Kojundo Chemical Laboratory Co., Ltd. was used. As an oxide of Si, SI014PB manufactured by Kojundo Chemical Laboratory Co., Ltd. manufactured by Kojundo Chemical Laboratory Co., Ltd. was used. As an oxide of Mo, M0001 PB manufactured by Kojundo Chemical Laboratory Co., Ltd. was used. As an oxide of W, WW004PB manufactured by Kojundo Chemical Laboratory Co., Ltd. was used. As an oxide of Zr, ZR002PB manufactured by Kojundo Chemical Laboratory Co., Ltd. was used.

The target of Example 12 was measured by EPMA. It was confirmed that it had an In-rich phase and a Ga-rich phase. Further, it was confirmed that the In-rich phase had a lower oxygen content than that in other layers. In addition, presence of Sn in the crystal structure represented by In₂O₃ was confirmed. The number of aggregated particles of tin oxide having a diameter of 10 μm or larger was 2.5 or less per 1.00 mm².

The surface area of the oxide of the positive tetravalent element X used in Examples 10 to 19 was as follows.

Tin oxide: 6 m²/g
Each oxide of Ge, Zr, Hf, Ti and Si: 10 m²/g
Each oxide of Mo and W: 8 m²/g

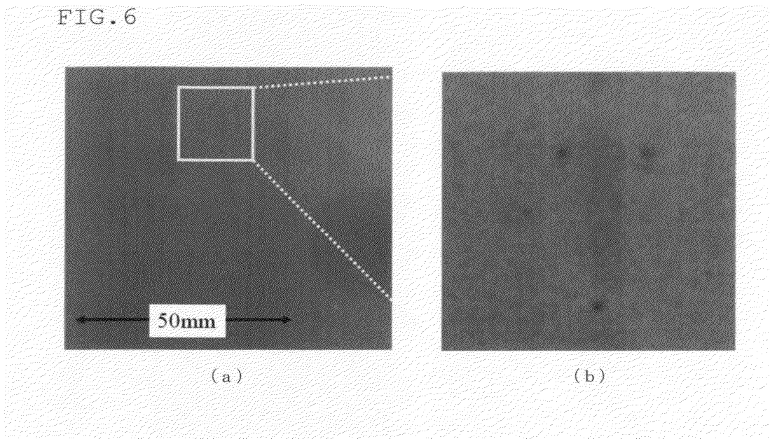

FIG. 6 is a photograph showing the black spots on the surface of the target prepared in Comparative Example 3. (b) is an enlarged photograph of (a).

The amounts of particles generated during DC sputtering in Example 3 and Comparative Example 10 were visually confirmed. After 120-hour continuous sputtering, the amount of particles adhered to the inner wall of the chamber in Comparative Example 10 was larger than that in Example 3.

TABLE 2

| | | | Examples | | | | | | |
|---|---|---|---|---|---|---|---|---|---|
| | | | 3 | 4 | 5 | 6 | 7 | 8 | 9 |
| Raw | Specific surface | In₂O₃ | 15 | 15 | 15 | 15 | 15 | 15 | 15 |
| material | area (m²/g) | Ga₂O₃ | 14 | 14 | 14 | 14 | 14 | 14 | 14 |
| | | ZnO | 4 | 4 | 4 | 4 | 4 | 4 | 4 |
| | | Oxide of X | — | — | — | — | — | — | — |
| Target | Composition ratio | In/(In + Ga + Zn) | 0.4 | 0.42 | 0.38 | 0.42 | 0.38 | 0.4 | 0.4 |
| | of elements | Ga/(In + Ga + Zn) | 0.4 | 0.4 | 0.4 | 0.38 | 0.42 | 0.38 | 0.42 |
| | (atomic ratio) | Zn/(In + Ga + Zn) | 0.2 | 0.18 | 0.22 | 0.2 | 0.2 | 0.22 | 0.18 |
| | Type of positive | X | — | — | — | — | — | — | — |
| | tetravalent element | | | | | | | | |
| | Composition ratio | X/(In + Ga + | — | — | — | — | — | — | — |
| | of elements | Zn + X) | | | | | | | |
| | (atomic ratio) | | | | | | | | |
| | Sintering | Sintering | 1300 | 1300 | 1300 | 1300 | 1300 | 1300 | 1300 |
| | conditions | temperature (° C.) | | | | | | | |
| | | Sintering time (Hr) | 20 | 20 | 20 | 20 | 20 | 20 | 20 |
| | Crystal system | In₂O₃ | \textcircled{2} | \textcircled{2} | \textcircled{2} | \textcircled{2} | \textcircled{2} | \textcircled{2} | \textcircled{2} |
| | of compound*¹ | ZnGa₂O₄ | \textcircled{1} | \textcircled{1} | \textcircled{1} | \textcircled{1} | \textcircled{1} | \textcircled{1} | \textcircled{1} |
| | | GaInO₃ | | | | | | | |
| | | In₂Ga₂ZnO₇ | | | | | | | |
| | | (Ga,In)₂O₃ | | | | | | | |
| | | Others | | | | | | | |

| | | | Examples | | | | | |
|---|---|---|---|---|---|---|---|---|
| | | | 10 | 11 | 12 | 13 | 14 | 15 |
| Raw | Specific surface | In₂O₃ | 15 | 15 | 15 | 15 | 15 | 15 |
| material | area (m²/g) | Ga₂O₃ | 14 | 14 | 14 | 14 | 14 | 14 |
| | | ZnO | 4 | 4 | 4 | 4 | 4 | 4 |
| | | Oxide of X | 6 | 6 | 6 | 10 | 10 | 10 |
| Target | Composition ratio | In/(In + Ga + Zn) | 0.4 | 0.4 | 0.4 | 0.4 | 0.4 | 0.4 |
| | of elements | Ga/(In + Ga + Zn) | 0.4 | 0.4 | 0.4 | 0.4 | 0.4 | 0.4 |
| | (atomic ratio) | Zn/(In + Ga + Zn) | 0.2 | 0.2 | 0.2 | 0.2 | 0.2 | 0.2 |
| | Type of positive | X | Sn | Sn | Sn | Ge | Zr | Hf |
| | tetravalent element | | | | | | | |
| | Composition ratio | X/(In + Ga + | 0.0005 | 0.01 | 0.03 | 0.0005 | 0.0005 | 0.0005 |
| | of elements | Zn + X) | | | | | | |
| | (atomic ratio) | | | | | | | |
| | Sintering | Sintering | 1300 | 1300 | 1300 | 1300 | 1300 | 1300 |
| | conditions | temperature (° C.) | | | | | | |
| | | Sintering time (Hr) | 20 | 20 | 20 | 20 | 20 | 20 |
| | Crystal system | In₂O₃ | \textcircled{2} | \textcircled{2} | \textcircled{2} | \textcircled{2} | \textcircled{2} | \textcircled{2} |
| | of compound*¹ | ZnGa₂O₄ | \textcircled{1} | \textcircled{1} | \textcircled{1} | \textcircled{1} | \textcircled{1} | \textcircled{1} |
| | | GaInO₃ | | | | | | |
| | | In₂Ga₂ZnO₇ | | | | | | |
| | | (Ga,In)₂O₃ | | | | | | |
| | | Others | | | | | | |

*¹Same as in Table 1.

TABLE 3

| | | | Examples | | | | | | Com. Ex. | |
|---|---|---|---|---|---|---|---|---|---|---|
| | | | 16 | 17 | 18 | 19 | 20 | 21 | 3 | 4 |
| Raw | Specific surface | In₂O₃ | 15 | 15 | 15 | 15 | 15 | 15 | 15 | 15 |
| material | area (m²/g) | Ga₂O₃ | 14 | 14 | 14 | 14 | 14 | 14 | 14 | 14 |
| | | ZnO | 4 | 4 | 4 | 4 | 4 | 4 | 4 | 4 |
| | | Oxide of X | 8 | 8 | 8 | 8 | — | — | — | — |
| Target | Composition ratio | In/(In + Ga + Zn) | 0.4 | 0.4 | 0.4 | 0.4 | 0.4 | 0.4 | 0.4 | 0.4 |
| | of elements | Ga/(In + Ga + Zn) | 0.4 | 0.4 | 0.4 | 0.4 | 0.4 | 0.4 | 0.4 | 0.4 |
| | (atomic ratio) | Zn/(In + Ga + Zn) | 0.2 | 0.2 | 0.2 | 0.2 | 0.2 | 0.2 | 0.2 | 0.2 |
| | Type of positive | X | Ti | Si | Mo | W | — | — | — | — |
| | tetravalent element | | | | | | | | | |
| | Composition ratio | X/(In + Ga + | 0.0005 | 0.0005 | 0.0005 | 0.0005 | — | — | — | — |
| | of elements | Zn + X) | | | | | | | | |
| | (atomic ratio) | | | | | | | | | |
| | Sintering | Sintering | 1300 | 1300 | 1300 | 1300 | 1200 | 1300 | 1400 | 1500 |
| | conditions | temperature(° C.) | | | | | | | | |
| | | Sintering time (Hr) | 20 | 20 | 20 | 20 | 20 | 2 | 2 | 2 |
| | Crystal system | In₂O₃ | \textcircled{2} | \textcircled{2} | \textcircled{2} | \textcircled{2} | \textcircled{2} | \textcircled{2} | | |
| | of compound *1 | ZnGa₂O₄ | \textcircled{1} | \textcircled{1} | \textcircled{1} | \textcircled{1} | \textcircled{1} | \textcircled{1} | | |
| | | GaInO₃ | | | | | | | | |
| | | In₂Ga₂ZnO₇ | | | | | | | \textcircled{1} | |
| | | (Ga,In)₂O₃ | | | | | | | | \textcircled{1} |
| | | Others | | | | | | | | |

| | | | Com. Ex. | | | | | |
|---|---|---|---|---|---|---|---|---|
| | | | 5 | 6 | 7 | 8 | 9 | 10 |
| Raw | Specific surface | In₂O₃ | 15 | 15 | 15 | 15 | 15 | 15 |
| material | area (m²/g) | Ga₂O₃ | 14 | 14 | 14 | 14 | 14 | — |
| | | ZnO | 4 | — | — | 4 | 4 | — |
| | | Oxide of X | — | — | — | — | 6 | — |
| Target | Composition ratio | In/(In + Ga + Zn) | 0.4 | 0.5 | 0.34 | 0.05 | 0.4 | 1 |
| | of elements | Ga/(In + Ga + Zn) | 0.4 | 0.5 | 0.66 | 0.65 | 0.4 | — |
| | (atomic ratio) | Zn/(In + Ga + Zn) | 0.2 | — | — | 0.3 | 0.2 | — |
| | Type of positive | X | — | — | — | — | Sn | — |
| | tetravalent element | | | | | | | |
| | Composition ratio | X/(In + Ga + | — | — | — | — | 0.8 | — |
| | of elements | Zn + X) | | | | | | |
| | (atomic ratio) | | | | | | | |
| | Sintering | Sintering | 1050 | 1400 | 1400 | 1500 | 1300 | 1500 |
| | conditions | temperature(° C.) | | | | | | |
| | | Sintering time (Hr) | 2 | 10 | 10 | 5 | 20 | 5 |
| | Crystal system | In₂O₃ | | | | | | \textcircled{1} |
| | of compound *1 | ZnGa₂O₄ | | | | \textcircled{1} | | |
| | | GaInO₃ | | \textcircled{1} | \textcircled{1} | | | |
| | | In₂Ga₂ZnO₇ | | | | | | |
| | | (Ga,In)₂O₃ | | | | | | |
| | | Others | \textcircled{1} | | | | \textcircled{1} | |

*1: Same as Table 1.

TABLE 4

| | | Examples | | | | | | | |
|---|---|---|---|---|---|---|---|---|---|
| | | 3 | 4 | 5 | 6 | 7 | 8 | 9 | 10 |
| Evaluation | Relative density (%) | 97 | 96 | 97 | 96 | 95 | 98 | 95 | 99 |
| of target | Resistivity (mΩcm) | 8 | 8 | 8 | 6 | 12 | 5 | 10 | 3 |
| | Density of black | 0.0 | 0.0 | 0.0 | 0.0 | 0.0 | 0.0 | 0.0 | 0.0 |
| | spots (number/cm²) | | | | | | | | |
| | Transverse rupture | 12.2 | 12.1 | 12.2 | 11.9 | 11.8 | 12.4 | 11.8 | 13.1 |
| | strength (kg/mm²) | | | | | | | | |
| | Cracking during sintering | B | B | B | B | B | B | B | A |
| | Abnormal discharge | A | A | A | A | A | A | A | A |
| | In-plane uniformity | A | A | A | A | A | A | A | A |
| Evaluation of | Abnormal discharge | <10 | <10 | <10 | <10 | <10 | <10 | <10 | <10 |
| RF sputtering | (times/96 hours) | | | | | | | | |
| | Generation of nodules | A | A | A | A | A | A | A | A |
| | Continuous stability | A | A | A | A | A | A | A | A |
| | In-plane uniformity | A | A | A | A | A | A | A | A |
| | Occurrence of cracking | A | A | A | A | A | A | A | A |
| | in target | | | | | | | | |
| Evaluation | Mobility (cm²/Vs) | 10 | 10 | 10 | 11 | 8 | 11 | 8 | 10 |
| of TFT | On-off ratio | 10⁹ | 10⁹ | 10⁹ | 10⁹ | 10⁹ | 10⁹ | 10⁹ | 10⁹ |
| | Uniformity of TFT | A | A | A | A | A | A | A | A |
| | properties | | | | | | | | |
| | Reproducibility | A | A | A | A | A | A | A | A |
| | of TFT properties | | | | | | | | |
| | Yield of TFT | A | A | A | A | A | A | A | A |

| | | Examples | | | | |
|---|---|---|---|---|---|---|
| | | 11 | 12 | 13 | 14 | 15 |
| Evaluation | Relative density (%) | 99 | 99 | >99 | 99 | 99 |
| of target | Resistivity (mΩcm) | 3 | 4 | 1 | 3 | 5 |
| | Density of black | 0.0 | 0.0 | 0.0 | 0.0 | 0.0 |
| | spots (number/cm²) | | | | | |
| | Transverse rupture | 13.5 | 14.2 | 14.3 | 14.3 | 13.8 |
| | strength (kg/mm²) | | | | | |
| | Cracking during sintering | A | A | A | A | A |
| | Abnormal discharge | A | A | A | A | A |
| | In-plane uniformity | A | A | A | A | A |
| Evaluation of | Abnormal discharge | <10 | <10 | <10 | <10 | <10 |
| RF sputtering | (times/96 hours) | | | | | |
| | Generation of nodules | A | A | A | A | A |
| | Continuous stability | A | A | A | A | A |
| | In-plane uniformity | A | A | A | A | A |
| | Occurrence of cracking | A | A | A | A | A |
| | in target | | | | | |
| Evaluation | Mobility (cm²/Vs) | 10 | 10 | 10 | 10 | 10 |
| of TFT | On-off ratio | 10⁹ | 10⁹ | 10⁹ | 10⁹ | 10⁹ |
| | Uniformity of TFT | A | A | A | A | A |
| | properties | | | | | |
| | Reproducibility | A | A | A | A | A |
| | of TFT properties | | | | | |
| | Yield of TFT | A | A | A | A | A |

TABLE 5

| | | Examples | | | | | | Com. Ex. | |
|---|---|---|---|---|---|---|---|---|---|
| | | 16 | 17 | 18 | 19 | 20 | 21 | 3 | 4 |
| Evaluation | Relative density (%) | 99 | 99 | 99 | 99 | 91 | 92 | 88 | 87 |
| of target | Registivity (mΩcm) | 5 | 5 | 5 | 5 | 25 | 12 | 42 | 2800 |
| | Density of black | 0.0 | 0.0 | 0.0 | 0.0 | 0.0 | 0.0 | 0.8 | 2.1 |
| | Spots (number/cm²) | | | | | | | | |
| | Transverse | 13.5 | 13.5 | 12.9 | 12.9 | 10.9 | 11.8 | 7.8 | 8.5 |
| | rupture strength | | | | | | | | |
| | (kg/mm²) | | | | | | | | |
| | Cracking during sintering | A | A | A | A | A | A | C | C |
| Evaluation of | Abnormal discharge | A | A | A | A | A | A | B | C |
| RF sputtering | In-plane uniformity | A | A | A | A | A | A | B | C |
| Evaluation of | Abnormal discharge | <10 | <10 | <10 | <10 | <10 | <10 | 120 | 130 |
| DC sputtering | (times/96 hours) | | | | | | | | |
| | Generation of nodules | A | A | A | A | A | A | B | B |
| | Continuous stability | A | A | A | A | A | A | B | C |
| | In-plane uniformity | A | A | A | A | A | A | B | C |
| | Occurrence of | A | A | A | A | A | A | B | B |
| | cracking In target | | | | | | | | |
| Evaluation | Mobility (cm²/Vs) | 10 | 10 | 10 | 10 | 10 | 10 | 7 | 7 |
| of TFT | On-off ratio | 10⁹ | 10⁹ | 10⁹ | 10⁹ | 10⁹ | 10⁹ | 10⁷ | 10⁷ |
| | Uniformity in TFT | A | A | A | A | A | A | B | B |
| | properties | | | | | | | | |
| | Reproducibility | A | A | A | A | A | A | B | B |
| | of TFT properties | | | | | | | | |
| | Yield of TFT | A | A | A | A | A | A | B | B |

| | | Com. Ex. | | | | | |
|---|---|---|---|---|---|---|---|
| | | 5 | 6 | 7 | 8 | 9 | 10 |
| Evaluation | Relative density (%) | 63 | 86 | 87 | 86 | 76 | 88 |
| of target | Registivity (mΩcm) | >5000 | >5000 | >5000 | >5000 | >5000 | 70 |
| | Density of black | 0.0 | 0.0 | 0.0 | 0.0 | 3.2 | 0.0 |
| | Spots (number/cm²) | | | | | | |
| | Transverse | 2.3 | 4.8 | 4.2 | 4.2 | 2.3 | 3.3 |
| | rupture strength | | | | | | |
| | (kg/mm²) | | | | | | |
| | Cracking during sintering | B | D | D | D | D | C |
| Evaluation of | Abnormal discharge | C | C | C | C | A | D |
| RF sputtering | In-plane uniformity | D | D | C | C | D | D |
| Evaluation of | Abnormal discharge | 100 | 100 | 50 | 40 | 800 | 1400 |
| DC sputtering | (times/96 hours) | | | | | | |
| | Generation of nodules | B | B | B | B | B | D |
| | Continuous stability | D | D | C | C | D | D |
| | In-plane uniformity | D | D | C | C | D | D |
| | Occurrence of | D | D | D | D | D | D |
| | cracking In target | | | | | | |
| Evaluation | Mobility (cm²/Vs) | 7 | 0.1 | Unmea- | Unmea- | 0.1 | Unmea- |
| of TFT | | | | surable | surable | | surable |
| | On-off ratio | 10⁷ | 10⁴ | Unmea- | Unmea- | 10⁴ | Unmea- |
| | | | | surable | surable | | surable |
| | Uniformity in TFT | C | C | D | D | C | D |
| | properties | | | | | | |
| | Reproducibility | C | C | D | D | C | D |
| | of TFT properties | | | | | | |
| | Yield of TFT | C | C | D | D | C | D |

### Comparative Example 11

A target and a thin film transistor were fabricated and evaluated in the same manner as in Example 3, except that sintering was conducted in the air at 1400° C. for 2 hours. The results are shown in Tables 6 and 7.

TABLE 6

| | | | Com. Ex. |
|---|---|---|---|
| | | | 11 |
| Raw material | Specific surface area | In₂O₃ | 15 |
| | (m²/g) | Ga₂O₃ | 14 |
| | | ZnO | 4 |
| | | Oxide of X | — |
| Target | Composition ratio of elements | In/(In + Ga + Zn) | 0.4 |
| | (atomic ratio) | Ga/(In + Ga + Zn) | 0.4 |
| | | Zn/(In + Ga + Zn) | 0.2 |
| | Type of positive tetravalent element | X | — |
| | Composition ratio of elements (atomic ratio) | X/(In + Ga + Zn + X) | — |
| | Sintering conditions | Sintering temperature (° C.) | 1400 |
| | | Sintering time (Hr) | 2 |
| | Crystal system of compound*¹ | In₂O₃ | \textcircled{3} |
| | | ZnGa₂O₄ | \textcircled{2} |
| | | GaInO₃ | |
| | | In₂Ga₂ZnO₇ | \textcircled{1} |
| | | (Ga,In)₂O₃ | |
| | | Others | |

*¹Same as in Table 1.
\textcircled{3} means the third component.

TABLE 7

| | | Com. Ex. |
|---|---|---|
| | | 11 |
| Evaluation of | Relative density (%) | 89 |
| target | Resistivity (mΩcm) | 20 |
| | Density of black spots (number/cm²) | 0.5 |
| | Transverse rupture strength (kg/mm²) | 9.2 |
| | Cracking during sintering | C |
| Evaluation of | Abnormal discharge | B |
| RF sputtering | In-plane uniformity | B |
| Evaluation of | Abnormal discharge (times/96 hours) | 80 |
| DC sputtering | Generation of nodules | B |
| | Continuous stability | B |
| | In-plane uniformity | C |
| | Occurrence of cracking in target | B |
| Evaluation of | Mobility (cm²/Vs) | 7 |
| TFT | On-off ratio | 10⁷ |
| | Uniformity of TFT properties | C |
| | Reproducibility of TFT properties | C |
| | Yield of TFT | B |

### INDUSTRIAL APPLICABILITY

The sputtering target of the invention can be suitably used for the formation of an oxide semiconductor film.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification are incorporated herein by reference in its entirety.

1. An oxide sintered body comprising In (indium element), Ga (gallium element) and Zn (zinc element), having a total content of In, Ga and Zn relative to total elements except for an oxygen element of 95 at % or more, and comprising a compound having a bixbyite structure represented by In₂O₃ and a compound having a spinel structure represented by ZnGa₂O₄.

2. The oxide sintered body according to claim 1, wherein the atomic ratio of Ga relative to the total of In, Ga and Zn satisfies the following formula (1) and the atomic ratio of Zn relative to the total of In, Ga and Zn satisfies the following formula (2):
0.20<Ga/(In+Ga+Zn)<0.49 (1)
0.10<Zn/(In+Ga+Zn)<0.30 (2).

3. The oxide sintered body according to claim 1, wherein one of the compound having a bixbyite structure represented by In₂O₃ and the compound having a spinel structure represented by ZnGa₂O₄ is the first (primary) component and the other is the second (sub) component.

4. The oxide sintered body according to claim 1, wherein, in the X-ray diffraction (XRD), the ratio (I(ZnGa₂O₄)/I(In₂O₃)) of the maximum peak intensity (I(In₂O₃)) of the compound having a bixbyite structure represented by In₂O₃ and the maximum peak intensity (I(ZnGa₂O₄)) of the compound having a spinel structure represented by ZnGa₂O₄ is 0.80 or more and 1.25 or less.

5. The sintered body according to claim 1, which has a relative density of 90% or more, a resistivity measured by the four probe method of 50 mΩcm or less and the number of black spots on the surface is 0.1/cm² or less.

6. The oxide sintered body according to claim 1, wherein the metal elements contained are substantially In, Ga and Zn.

7. The oxide sintered body according to claim 1, which further comprises a positive tetravalent element X, wherein the atomic ratio of X relative to the total of In, Ga, Zn and X satisfies the following formula (3):
0.0001<X/(In+Ga+Zn+X)<0.05 (3).

8. The oxide sintered body according to claim 7, wherein X is at least one selected from the group consisting of Sn, Ge, Zr, Hf, Ti, Si, Mo and W.

9. The oxide sintered body according to claim 7 wherein the metal element contained is substantially In, Ga, Zn and the positive tetravalent element X.

10. A sputtering target comprising the oxide sintered body according to claim 1.

11. A method for producing the oxide sintered body according to claim 1, which comprises the step of sintering a shaped body formed of a raw material comprising indium oxide powder, gallium oxide powder and zinc oxide powder at 1160 to 1380° C. for 1 to 80 hours.

12. The method for producing the oxide sintered body according to claim 11, wherein the pressurization with oxygen during the sintering step is conducted at 1 to 3 atmospheric pressures.

13. The method for fabricating a semiconductor device which comprises the step of forming an amorphous oxide film by using the sputtering target according to claim 10.
